(19) United States
(12) Patent Application Publication
(10) Pub. No.: US 2002/0132191 A1
(43) Pub. Date: Sep. 19, 2002

(54) Method for forming a contact pad

(76) Inventor: Shu-Ya Chuang, Hsin-Chu Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 09/803,882

(22) Filed: Mar. 13, 2001

(51) Int. Cl. G03F 7/00

(52) U.S. Cl. 430/314; 430/311; 430/313; 430/316; 430/317

(57) ABSTRACT

The present invention provides a method for forming a share contact pad on a semiconductor wafer. The semiconductor wafer comprises a first and second gate positioned on the substrate, each gate having a plurality of first spacers around the wall of the gate. The method of present invention first involves forming a silicon layer and a mask on the semiconductor wafer. Next, second spacers are formed around the mask. Portions of the silicon layer not covered by the mask or the second spacers are removed. Thereafter, the mask and the second spacers are removed and a silicide layer is formed on the residual silicon layer so as to form the share contact pad for connecting the first gate to a doped region adjacent to the second gate. Finally, an insulating layer is formed on the surface of the semiconductor wafer to cover the share contact pad, the two gates and each first spacer.

### BACKGROUND OF THE INVENTION

1. Field of the Invention

The present invention relates to a method of forming a share contact pad.

2. Description of the Prior Art

Dynamic random access memory (DRAM) is a collection of a large number of memory cells. Each of the memory cells has a metal oxide semiconductor (MOS) transistor in series with a capacitor. In order to electrically connect a drain of a MOS transistor to a storage node of the capacitor, a node contact is formed by filling doped polysilicon into a contact hole. The node contact enables the reading and writing of data that is electrically stored in the capacitor.

As the design size of semiconductor devices decreases, the process margin correspondingly decreases. Therefore, difficulty occurs in etching a contact hole to accurately define the position of a contact plug. In present processes, a contact pad is usually formed above the drain of a MOS transistor both to prevent misalignment when manufacturing the contact hole and for electrically connecting the MOS transistor to the capacitor.

Please refer to FIG. 1 to FIG. 6. FIG. 1 to FIG. 6 are cross-sectional diagrams of a method of forming a contact pad according to the prior art, of which the method is disclosed in U.S. patent (U.S. Pat. No. 6,071,802) of Ban et al. in July, 2000. The prior method of forming a contact pad is performed on a semiconductor wafer 10. As shown in FIG. 1, the semiconductor wafer 10 comprises a silicon substrate 12 and at least one active area positioned in a predetermined area (not shown) on the silicon substrate 12. Each active and non-active area is separated by field oxide layers 14. A plurality of neighboring gates 16 are positioned in the active area. A plurality of doped regions (not shown) are respectively positioned in the substrate 12 adjacent to each gate 16, and a salicide layer (not shown) is formed on each gate 16 and doped region. A spacer 18, composed of silicon nitride, is positioned on either side of each gate 16.

As shown in FIG. 2, the prior art method of manufacturing a contact pad involves first depositing a silicon nitride layer 20 on the semiconductor wafer 10 to function as an etch stop layer. Next, as shown in FIG. 3, a first silicon oxide layer 22 is deposited on the semiconductor wafer 10. As shown in FIG. 4, a chemical-mechanical polishing (CMP) process is performed using the silicon nitride layer 20 as the end-point for leveling the first silicon oxide layer 22. Thereafter, a chemical vapor deposition (CVD) process is performed to deposit a second silicon oxide layer 24 on the planarized first silicon oxide layer 22. The second silicon oxide layer 24 coupled with the first silicon oxide layer 22 form an inter-layer dielectric (ILD) layer 25.

As shown in FIG. 5, a photolithographic process is performed to define a plurality of contact plug patterns on the ILD layer 25, and each contact hole 26 is formed by etching through the ILD layer 25 to the silicon nitride layer 20. Finally as shown in FIG. 6, a conductive layer 28 is deposited on the semiconductor wafer 10 for filling each contact hole 26. Next, a CMP or an etch-back process is performed to align the surface of the conductive layer 28 with that of the ILD layer 25. The bottom surface of the conductive layer 28 is used as a contact plug and the top surface of the conductive layer 28 is used as a contact pad 30.

However, both a share contact plug and a borderless contact plug normally coexist in the design layout and differ in size. The share contact plug requires a larger area and functions in connecting gates and doped regions between different word lines. Therefore, in the prior art method of manufacturing contact plugs, two mask and etching processes must be performed to result in both an increase in the complexity of process and a decrease in the accuracy of alignment. Also, since the ILD layer 25 is composed of silicon oxide and the etch-stop layer 20 and the spacer 18 are both composed of silicon nitride, the surfaces of the gate 16 and adjacent spacers 18 are easily damaged during the etching process because of the difficulty in adjusting the etching selectivity ratio of silicon nitride to silicon oxide at an optimal condition. Furthermore, junction leakage occurs between the gate 16 and the contact plug so as to affect the electrical performance of the semiconductor wafer 10.

### SUMMARY OF THE INVENTION

It is therefore a primary objective of the present invention to provide a method of forming a contact pad on the semiconductor wafer to solve the above-mentioned problems.

In a preferred embodiment, the semiconductor wafer comprises a first and second gate positioned on the substrate, each gate having a plurality of first spacers positioned around the gate. The method of the present invention involves first forming a silicon layer and a mask on the semiconductor wafer. Next, second spacers are formed around the mask and the portions of the silicon layer not covered by the mask or the second spacers are removed. Thereafter, the mask and the second spacers are removed and a silicide layer is formed on the residual silicon layer so as to form a share contact pad for connecting the first gate to a doped region adjacent the second gate. Finally, an insulating layer is formed on the surface of the semiconductor wafer to cover the share contact pad, the two gates and each first spacer.

The contact pad manufactured by the present invention uses a silicide layer as a share contact pad so as to decrease the area of the share contact plug and unify the sizes of the share contact plug and a borderless contact pad to simplify the complexity of process. As well, because there is a good etching selectivity ratio between silicide and silicon oxide, the junction leakage caused by the damage of spacers is prevented by using the silicide layer as an etching stop layer.

These and other objectives of the present invention will no doubt become obvious to those of ordinary skill in the art after reading the following detailed description of the preferred embodiment, which is illustrated in the various figures and drawings.

### BRIEF DESCRIPTION OF THE DRAWINGS

FIG. 1 to FIG. 6 are cross-sectional diagrams of a method of forming a contact pad according to the prior art.

FIG. 7 is a schematic diagram of a contact pad manufactured by the present invention.

FIG. 8 to FIG. 13 are cross-sectional diagrams along line 1-1′ of the manufacturing process of the contact pad shown in FIG. 7.

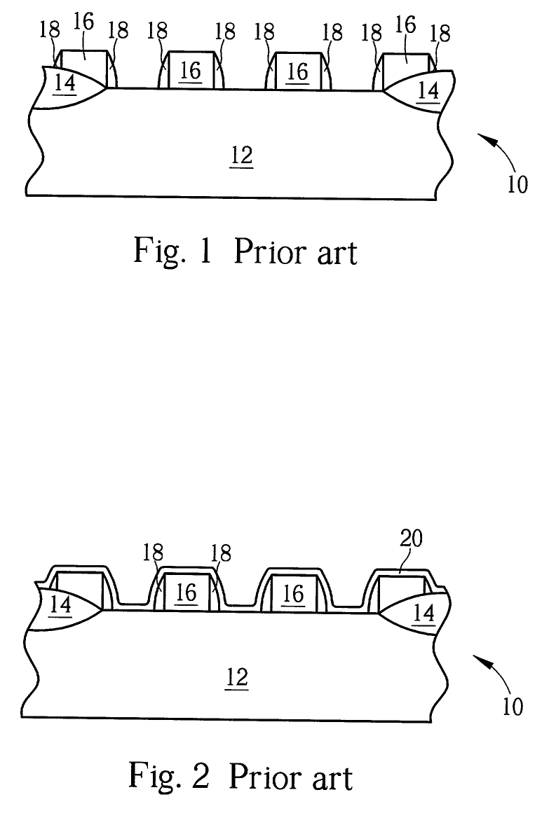

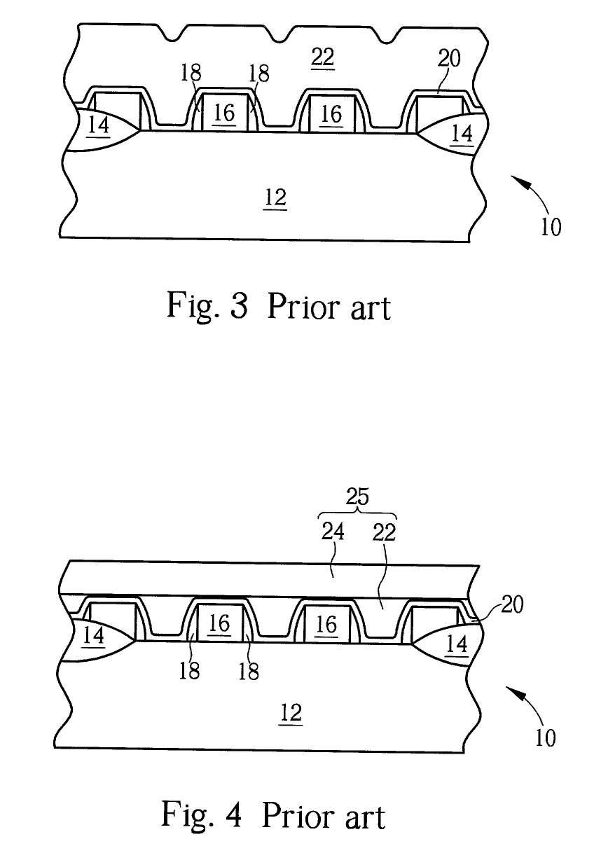

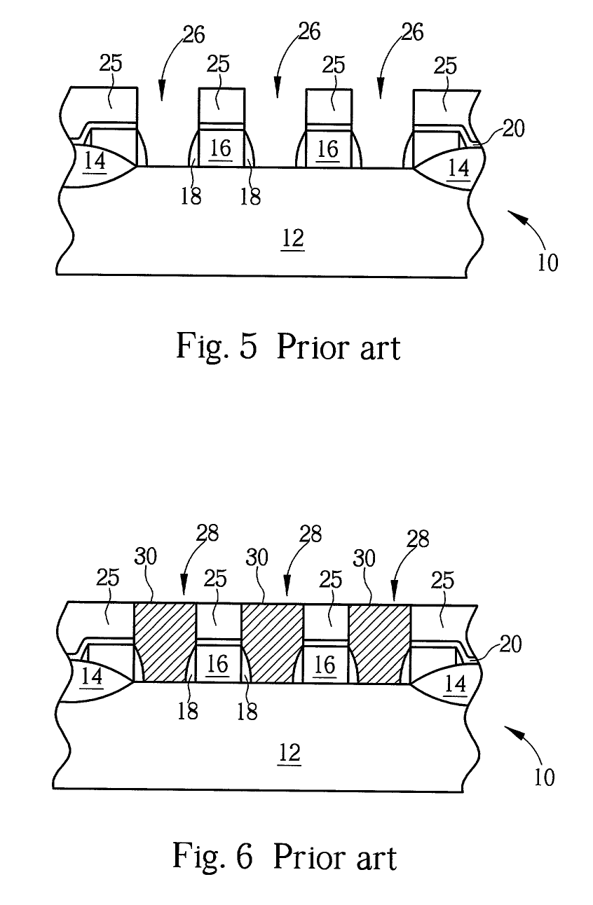

### DETAILED DESCRIPTION OF THE PREFERRED EMBODIMENT

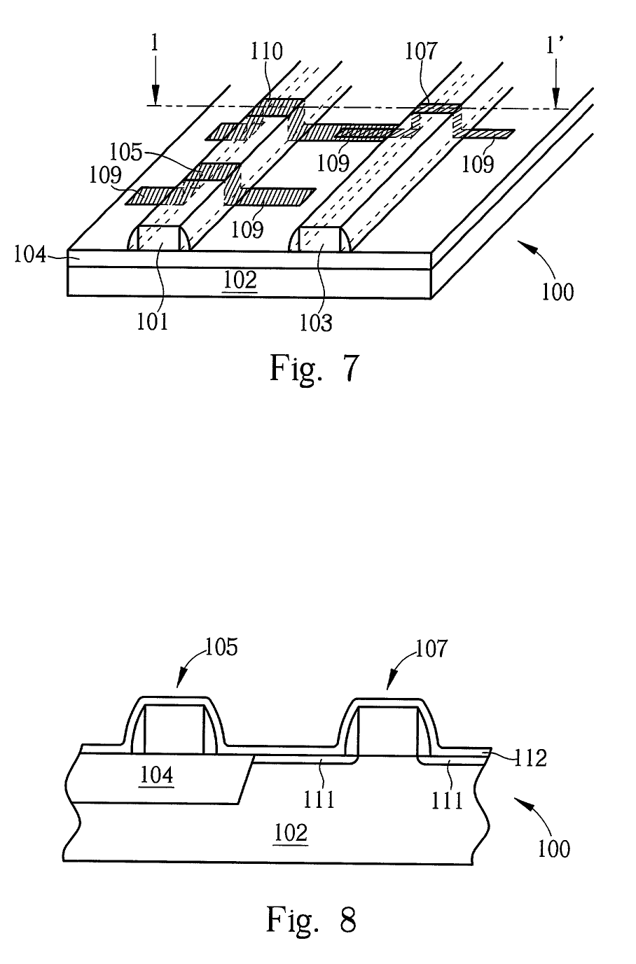

Please refer to FIG. 7. FIG. 7 is a schematic diagram of a contact pad manufactured by the present invention. As shown in FIG. 7, the silicon substrate 102 of the semiconductor wafer 100 comprises two parallel word lines 101, 103, and each word line is separated by a shallow trench isolation (STI) structure 104. Each word line 101, 103 comprises a gate 105, 107, respectively, and each gate 105, 107 has two correspondingly doped regions 109 adjacent to each gate 105, 107. A contact pad 110 is formed between two word lines 101, 103 covering portions of both the word line 110 and the doped region 109 of gate 107 to connect the gate 105 to the doped region 109 of gate 107.

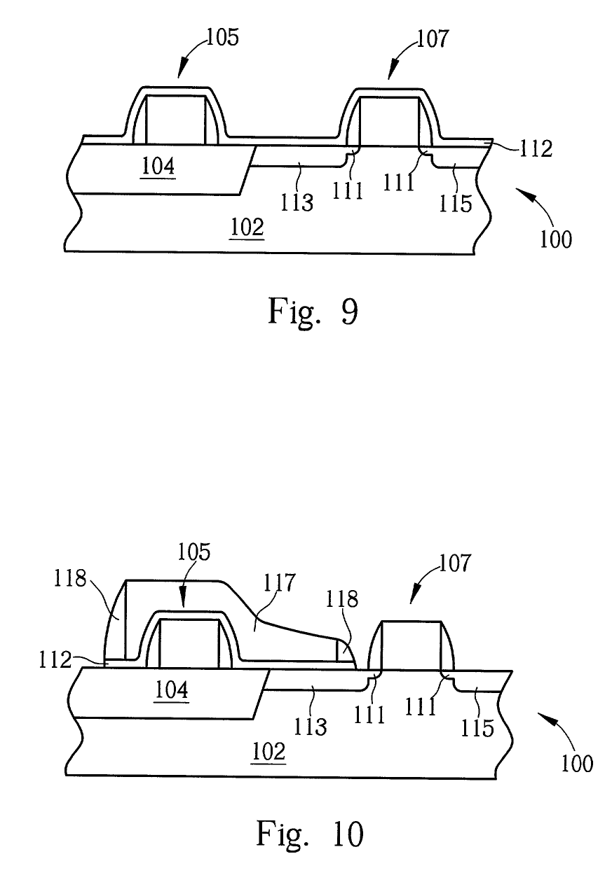

Please refer to FIG. 8 to FIG. 13. FIG. 8 to FIG. 13 are cross-sectional diagrams along line 1-1′ of the manufacturing process of the contact pad shown in FIG. 7. As shown in FIG. 8, the semiconductor wafer 100 comprises a silicon substrate 102, two parallel word lines (not shown) positioned on the substrate 102, each word line separated by a STI structure 104. Gates 105, 107 are respectively positioned on the two word lines, and a lightly doped drain (LDD) 111 is formed adjacent to each gate 105, 107. As shown in FIG. 7, the two gates 105, 107 are not in the same vertical cross-section. The gate 105 is positioned in the front vertical cross-section and the gate 107 is positioned in the back vertical cross-section. First, a silicon layer 112 composed of polysilicon, amorphous silicon, or any kind of a conductive layer is formed on the semiconductor wafer 100. Next, as shown in FIG. 9, an ion implantation process is performed to form a source 113 and a drain 115 for each gate 105, 107, and an anneal process is used to diffuse doped ions into the silicon layer 112.

Then, as shown in FIG. 10, a first dielectric layer 117 is formed on the silicon layer 112. The mask patterns of both the share contact pad and borderless contact pad are defined on the first dielectric layer 117, and excess of the first dielectric layer 117 is removed. Thereafter, a second dielectric layer (not shown) is formed on the first dielectric layer 117 and the silicon layer 112, followed by an etch-back process to form spacers 118 around each mask for increasing the tolerance of misalignment in the subsequent process of forming the share contact pad or the borderless contact pad. Then, the silicon layer 112 not covered by the mask or the spacer 118 is removed. The mask and the spacer 118 are both composed of nonmetallic materials such as silicon oxide, silicon nitride and titanium, nitride or metallic materials such titanium and cobalt. When the mask and the spacer 118 are both composed of nonmetallic materials, a wet-etching process is performed to remove the mask and spacer 118 after removing the silicon layer 112 not covered by the mask or the spacer 118. When the mask and the spacer 118 are both composed of metallic materials, it is not necessary to remove the mask and the spacer 118.

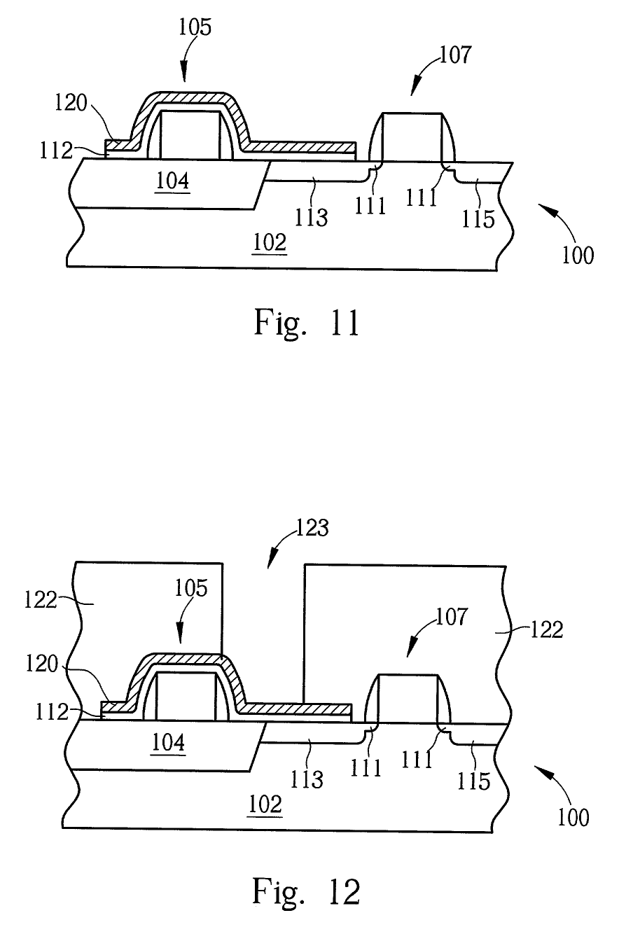

As shown in FIG. 11, a metal layer (not shown) is formed on the residual silicon layer 112 and the substrate 102 followed by forming a barrier layer (not shown) on the metal layer. Next, a thermal process is performed to allow reaction of the metal layer with the silicon layer 112 to form a silicide layer 120. Finally, the barrier layer and portions of the metal layer that do not react with the silicon layer 112 are removed.

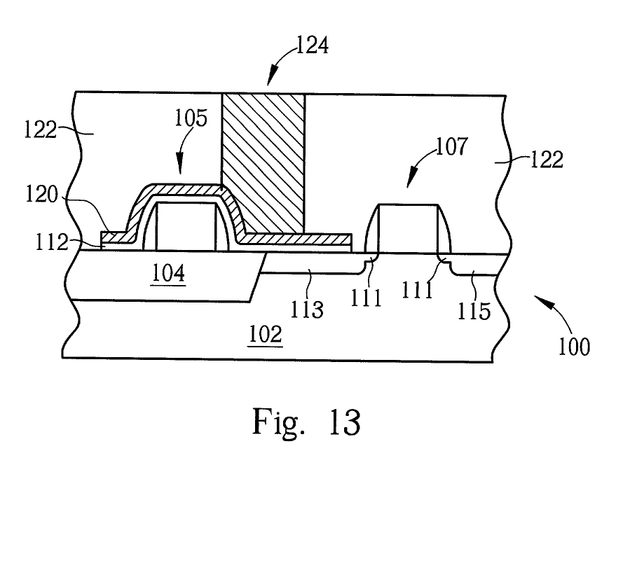

As shown in FIG. 12, an ILD layer 122 is formed on the semiconductor wafer 100. A photolithographic process is then performed to define patterns of each contact plug followed by etching down the ILD layer 122 to the surface of the silicide layer 120 to form each contact plug hole 123. Finally, as shown in FIG. 13, a conductive layer 124 is filled into the contact plug hole 123. The conductive layer 124 is used as a contact plug, and the silicide layer 120 at the bottom surface of the conductive layer 124 is the contact pad 110 shown in FIG. 7. The contact pad 110 is used to connect the gate 105 to the source 113 of the gate 107 for forming a share contact pad.

The present invention method of forming a contact pad involves first forming a silicon layer on the semiconductor wafer. Then, a silicon oxide layer is used as a mask to define patterns of both a share contact pad and borderless contact pad. Finally, a silicide layer is formed on the residual silicon layer to connect a word line, comprising a gate, to a doped region of another gate in the active area so as to form a share contact pad.

In contrast to the prior art method of forming a contact pad, the contact pad manufactured by the present invention is used to connect a word line, comprising one gate, to a doped region of another gate so as to form a share contact pad. Therefore, both the area of the share contact pad and the borderless contact pad are the same so as to decrease the number of masks used in the process to thereby decrease the complexity and increase the accuracy of process. As well, the present invention uses the silicide layer as an etch-stop layer in the process of manufacturing the contact plug hole. Therefore, the prior art step of removing a silicon nitride layer, functioning an etch-stop layer, from the bottom surface of the contact plug hole is omitted. Additionally, since a good etching selectivity ratio occurs between silicide and silicon oxide, junction leakage caused by damage of the gate and adjacent spacers is prevented due to removal of the prior art use of the silicon nitride layer as an etch-stop layer.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A method for forming a contact pad on a semiconductor wafer, the semiconductor wafer comprising a substrate, at least an active area positioned on the substrate, two adjacent gates positioned inside the active area, each gate having two doped regions positioned in the substrate adjacent to the gate, and each gate having a first spacer disposed on the wall of the gate, the method comprising:
forming a silicon layer on the semiconductor wafer;
forming a mask on the surface of the silicon layer;
forming second spacers around the mask;
removing the portions of the silicon layer that are not covered by the mask or the second spacers;
removing the mask and the second spacers; and
forming a silicide layer on the residual silicon layer so as to form the contact pad; and
forming a insulating layer on the surface of the semiconductor wafer covers the share contact pad, the two gates and each first spacer;
wherein the contact pad is used to electrically connect a word line that is electrically connected to one of the two gates to one of the doped regions of the other gate, so as to form a shared contact pad.

2. The method of claim 1 wherein the silicon layer is a polysilicon layer or an amorphous silicon layer.

3. The method of claim 1 wherein the method for forming the mask and the second spacers comprises:
forming a first dielectric layer on the silicon layer;
defining patterns of the mask on the surface of the first dielectric layer, and removing the excess portions of the first dielectric layer so as to form the mask;
forming a second dielectric layer on the first dielectric layer and on the silicon layer; and
performing an etch back process so as to form the second spacers around the mask.

4. The method of claim 3 wherein the patterns of the mask comprises the patterns of the shared contact pad and the patterns of at least a borderless contact pad.

5. The method of claim 1 wherein the mask and the second spacers are all composed of nonmetallic materials.

6. The method of claim 5 wherein the nonmetallic materials contain silicon oxide, silicon nitride and titanium nitride.

7. The method of claim 1 wherein the mask and the second spacers are all composed of metallic materials.

8. The method of claim 7 wherein the metallic materials contain titanium and cobalt.

9. The method of claim 5 wherein the method for removing the mask and the second spacers involves a wet etching process.

10. The method of claim 1 wherein the method for forming the silicide layer comprises:
forming a metal layer on the surface of the residual silicon layer and the surface of the substrate;
forming a barrier layer on the metal layer;
performing a thermal process to make the metal layer interact with the silicon layer so as to form the silicide layer; and
removing the barrier layer and portions of the metal layer that are unreacted.

11. A method for forming an interconnect contact pad on a semiconductor wafer, the semiconductor wafer comprising a substrate, at least an active area positioned on the substrate, two adjacent gates positioned inside the active area, each gate having two doped regions positioned in the substrate adjacent to the gate, and each gate having a first spacer disposed on the walls of the gate, the method comprising:
forming a conductive layer on the semiconductor wafer;
forming a mask on the surface of the conductive layer so as to define patterns of the interconnect contact pad;
removing the portions of the conductive layer that are not covered by the mask so as to form the interconnect contact pad, wherein the interconnect contact pad is used to electrically connect a word line that is electrically connected to one of the two gates to one of the doped regions of the other gate;
removing the mask; and
forming a first dielectric layer on the semiconductor wafer.

12. The method of claim 11 wherein the conductive layer is a silicide layer formed by a sputtering method.

13. The method of claim 11 wherein the patterns of the mask comprises the patterns of the interconnect contact pad and the patterns of at least a borderless contact pad.

14. The method of claim 11 wherein the method for forming the mask comprises:
forming a second dielectric layer on the conductive layer;
defining patterns of the mask on the surface of the second dielectric layer, and removing excess portions of second dielectric layer;
forming a third dielectric layer on the second dielectric layer and on the conductive layer; and
performing an etch back process so as to form second spacers around the residual second dielectric layer, the residual second dielectric layer and the second spacers together forming the mask.

15. The method of claim 14 wherein the second dielectric layer and the third dielectric layer are both composed of nonmetallic materials such as silicon oxide, silicon nitride and titanium, nitride or metallic materials such titanium and cobalt.

16. The method of claim 11 wherein the method for removing the mask composed of nonmetallic materials is a wet etching process.
